(19) United States
(12) Patent Application Publication
(10) Pub. No.: US 2017/0029275 A1
(43) Pub. Date: Feb. 2, 2017

(54) VISIBLE/INFRARED ABSORBER VERTICALLY ALIGNED CARBON NANOTUBE NANOCOMPOSITE APPLIQUE

(71) Applicant: Northrop Grumman Systems Corporation, Falls Church, VA (US)

(72) Inventors: John A. Starkovich, Redondo Beach, CA (US); Hsiao H. Peng, Rancho Palos Verdes, CA (US); Jesse B. Tice, Torrance, CA (US); Edward M. Silverman, Encino, CA (US)

(21) Appl. No.: 14/809,962

(22) Filed: Jul. 27, 2015

(51) Int. Cl. C01B 31/02; H01J 37/32; C09D 175/04; G02B 1/04; G02B 5/20

(52) U.S. Cl. CPC C01B 31/0226; G02B 1/04; G02B 5/208; C09D 175/04; H01J 37/32009; C01B 2202/08; B82Y 40/00

(57) ABSTRACT

A method for making a vertically aligned carbon nanotube (VACNT) nanocomposite applique includes: growing a VACNT array on a substrate; treating the VACNT array with a polymer solution; performing one or more of curing and drying the polymer; and etching a surface of the polymer-VACNT nanocomposite to remove some of the polymer and to expose a portion of the VACNT. A vertically aligned carbon nanotube (VACNT) nanocomposite applique includes: a VACNT array; and a polymer solution with which the VACNT array is treated, wherein a surface of the polymer-VACNT nanocomposite is etched so as to do one or more of removing some of the polymer and exposing a portion of the VACNT.

### GOVERNMENT CONTRACT

The Government of the United States of America has rights in this invention pursuant to Government Contract No. 11-C-0042.

### SUMMARY

A method for making a vertically aligned carbon nanotube (VACNT) nanocomposite applique comprises: growing a VACNT array on a substrate; treating the VACNT array with a polymer solution; curing the polymer; and etching a surface of the polymer-VACNT nanocomposite to remove some of the polymer and to expose a portion of the VACNT.

A vertically aligned carbon nanotube (VACNT) nanocomposite applique comprises: a VACNT array; and a polymer solution with which the VACNT array is treated, wherein a surface of the polymer-VACNT nanocomposite is etched so as to do one or more of removing some of the polymer and exposing a portion of the VACNT.

A method for making a vertically aligned carbon nanotube (VACNT) nanocomposite applique comprises: growing a VACNT array on a substrate to a height between approximately 50 microns and approximately 200 microns with a density between approximately 3% and approximately 20%; treating the VACNT array with a polymer solution; curing the polymer; and etching a surface of the polymer-VACNT nanocomposite with plasma to remove some of the polymer and to expose a portion of the VACNT.

### DESCRIPTION OF THE DRAWINGS

The accompanying drawings provide visual representations which will be used to more fully describe various representative embodiments and can be used by those skilled in the art to better understand the representative embodiments disclosed herein and their advantages. In these drawings, like reference numerals identify corresponding elements.

FIG. 1 is a schematic cross-sectional drawing of a vertically aligned carbon nanotube (VACNT) visible/infrared absorber nanocomposite applique.

FIGS. 2A-2C is a set of three photomicrographs of polyurethane-infused vertically aligned carbon nanotube (VACNT) absorber nanocomposite appliques, showing an as-produced applique, a surface-etched plasma-etched applique, and an applique surface-etched with one or more solvents that dissolve polyurethane.

FIG. 3 is a graph of nanoabsorber material reflectance against wavelength for embodiments of the invention using a PU-infused, plasma-etched vertically aligned carbon nanotube (VACNT) applique and for leading existing commercial optical blacks.

FIG. 4 is a flowchart of a method for making a vertically aligned carbon nanotube (VACNT) nanocomposite applique according to embodiments of the invention.

FIG. 5 is a flowchart of a method for making a vertically aligned carbon nanotube (VACNT) nanocomposite applique according to embodiments of the invention.

### DETAILED DESCRIPTION

While the present invention is susceptible of embodiment in many different forms, there is shown in the drawings and will herein be described in detail one or more specific embodiments, with the understanding that the present disclosure is to be considered as exemplary of the principles of the invention and not intended to limit the invention to the specific embodiments shown and described. In the following description and in the several figures of the drawings, like reference numerals are used to describe the same, similar or corresponding parts in the several views of the drawings.

The present disclosure describes a method for preparing robust flexible appliques or films from delicate carbon nanotubes together with a post-assembly treatment method for maintaining or restoring their excellent absorber properties, enabling their practical use in terrestrial and space applications.

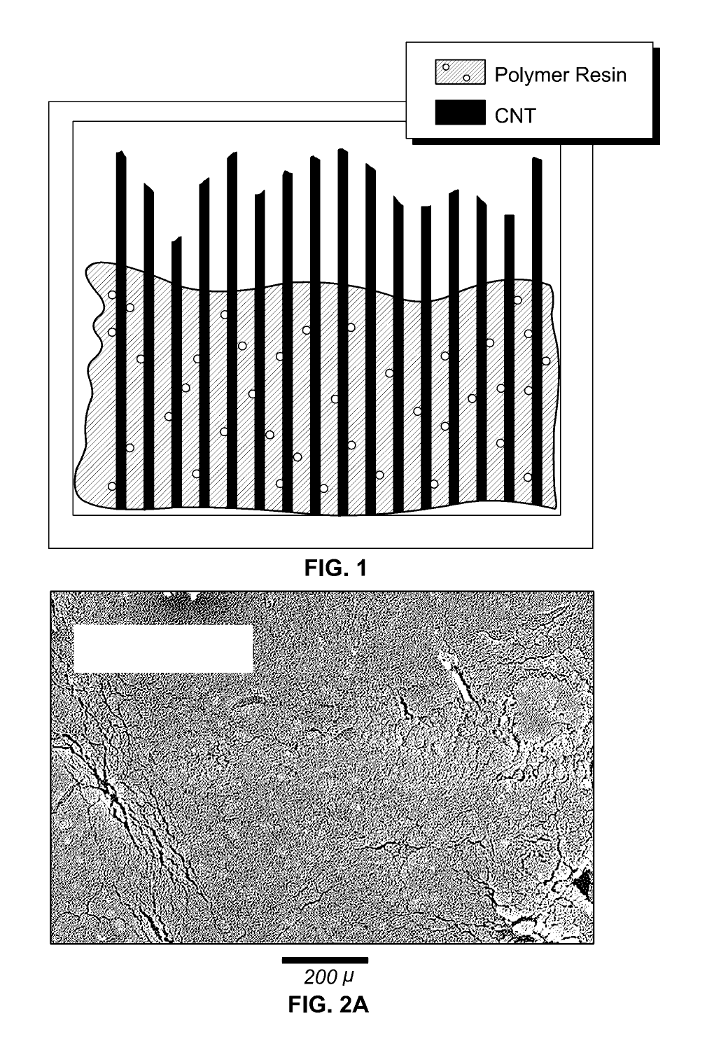

FIG. 1 is a schematic cross-sectional drawing of a vertically aligned carbon nanotube (VACNT) visible/infrared absorber nanocomposite applique.

According to embodiments of the invention, following one or more of curing and drying the polymer, a surface of the polymer-VACNT nanocomposite is etched. For example, the etching is performed with plasma. For example, the plasma treatment removes the polymer surface layer to a sufficient depth so that the light absorbing properties are restored while maintaining one or more of the mechanical integrity and the mechanical strength of the nanocomposite applique.

According to embodiments of the invention, mechanically robust polymer-infused VACNT array appliques can be prepared that have—relative to current commercial products—one or more of superior visible wavelength absorption properties and superior infrared (IR) wavelength absorption properties. With special processing following polymer infusion, unusually low (less than approximately 1-2%) reflectance properties can be restored while maintaining the mechanical strength/integrity afforded by a polymer nanocomposite.

Restoration of the VACNT array optical properties is achieved by selectively removing polymer resin from the optical working surface re-exposing the CNT tips/ends and creating a mottled textured surface having multi-spatial frequency character. VACNT arrays may be grown in the conventional manner on catalytically seeded silicon, quartz and other substrate materials. Growth conditions are adjusted to produce arrays with heights varying from 50 to over 200 um and densities ranging from 3 to 20%. While still attached to their growth substrate, the arrays may be treated with a dilute monomer or polymer solution that wets and fills the array. Polyurethane polymer has been successfully used for making nanocomposite appliques. The nanocomposite is cured or dried and next exposed to an etch treatment with one or more of reduced pressure oxygen and ambient pressure oxygen etch treatment to performing one or more of gasifying resin and removing resin at the exposed surface. The etch treatment also may remove some carbon nanotube at the exposed surface.

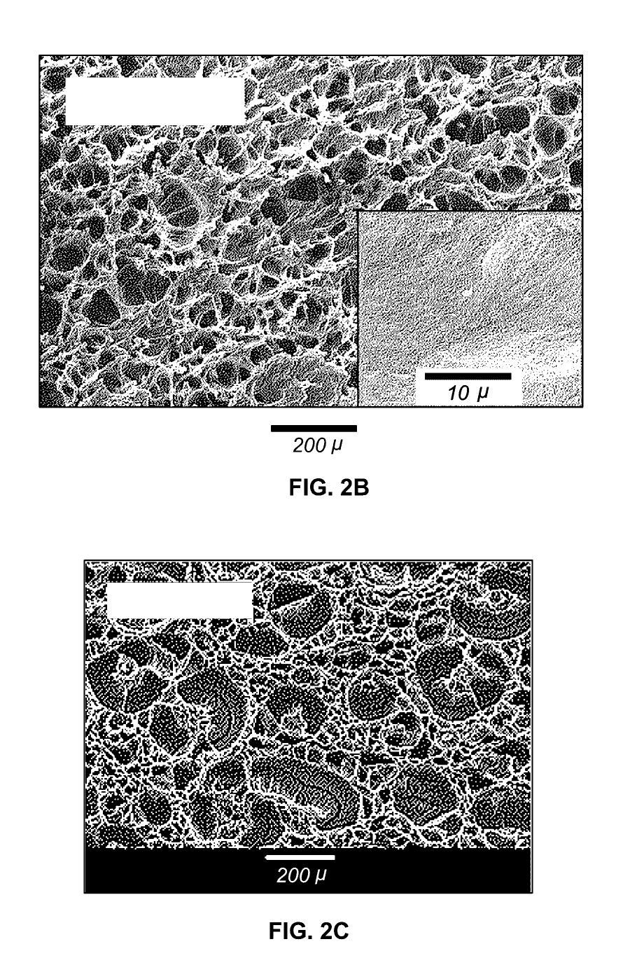

FIGS. 2A-2C is a set of three photomicrographs of polyurethane-infused vertically aligned carbon nanotube (VACNT) absorber nanocomposite appliques. FIG. 2A is a photomicrograph of an as-produced applique. FIG. 2B is a photomicrograph of a surface-etched plasma-etched applique according to embodiments of the invention. Dramatic surface morphology changes occur after plasma treatment according to embodiments of the invention. FIG. 2C is a photomicrograph of an applique surface-etched with one or more solvents that dissolve polyurethane according to embodiments of the invention.

Alternatively, solvent treatment of the applique may be used for etching and introduction of similar porosity and surface texturing.

VACNT array strength and handleability may be greatly enhanced by carefully infusing the delicate porous arrays with certain low (less than approximately 100 pascal-seconds [PaS]) viscosity polymer resins such as polyurethanes, silicones, epoxies, polyetherether ketones, etc., forming one or more of a robust freestanding nanocomposite applique and film. The polymer resin may be either thermoplastic or thermosetting.

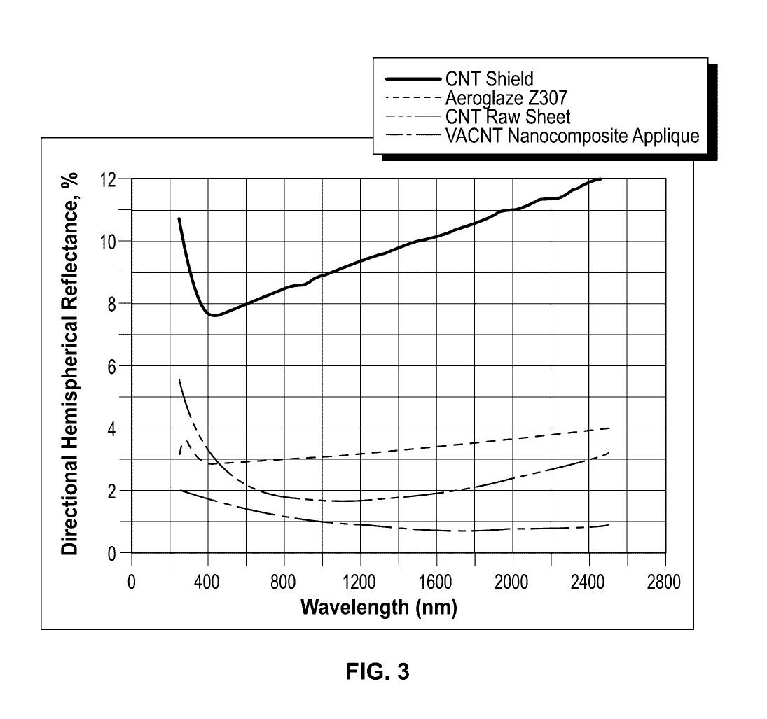

FIG. 3 is a graph of nanoabsorber material reflectance against wavelength in nanometers (nm) for embodiments of the invention using a PU-infused, plasma-etched vertically aligned carbon nanotube (VACNT) applique and for leading existing prior art alternatives. FIG. 3 graphically demonstrates the dramatic improvements over the prior art that are available according to embodiments of the invention. VACNT nanocomposite reflectance properties are compared in this figure with other CNT materials (a CNT raw sheet and a CNT shield) and the aerospace industry standard black paint Aeroglaze Z307).

FIG. 3 graphically illustrates the dramatically superior performance of embodiments of the invention relative to currently available alternatives.

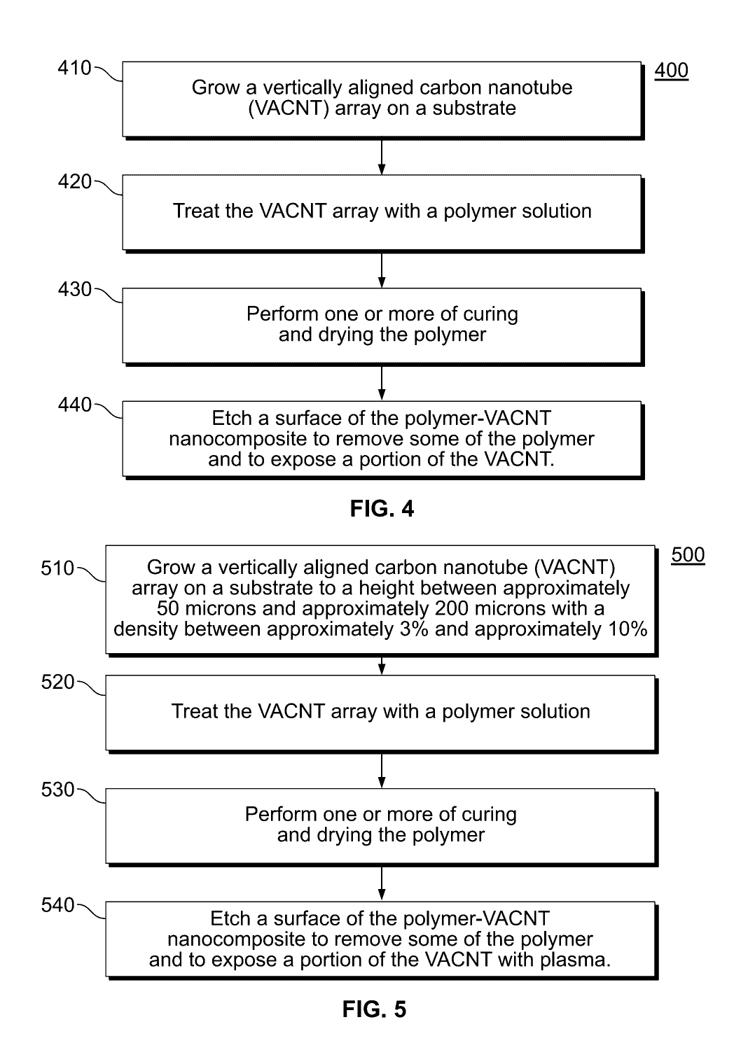

FIG. 4 is a flowchart of a method 400 for making a vertically aligned carbon nanotube (VACNT) nanocomposite applique according to embodiments of the invention. The order of the steps in the method 400 is not constrained to that shown in FIG. 4 or described in the following discussion. Several of the steps could occur in a different order without affecting the final result.

In step 410, a vertically aligned carbon nanotube (VACNT) array is grown on a substrate. Block 410 then transfers control to block 420.

In step 420, the VACNT array is treated with a polymer solution. Block 420 then transfers control to block 430.

In step 430, the polymer is cured. Block 430 then transfers control to block 440.

In step 440, a surface of the polymer-VACNT nanocomposite is etched to remove some of the polymer and to expose a portion of the VACNT. Block 440 then terminates the process.

FIG. 5 is a flowchart of a method 500 for making a vertically aligned carbon nanotube (VACNT) nanocomposite applique according to embodiments of the invention. The order of the steps in the method 500 is not constrained to that shown in FIG. 4 or described in the following discussion. Several of the steps could occur in a different order without affecting the final result.

In step 510, a vertically aligned carbon nanotube (VACNT) array is grown on a substrate to a height between approximately 50 microns and approximately 200 microns with a density between approximately 3% and approximately 20%. Block 510 then transfers control to block 520.

In step 520, the VACNT array is treated with a polymer solution. Block 520 then transfers control to block 530.

In step 530, the polymer is cured. Block 530 then transfers control to block 540.

In step 540, a surface of the polymer-VACNT nanocomposite is etched with plasma to remove some of the polymer and to expose a portion of the VACNT. Block 540 then terminates the process.

One benefit of the invention is that relative to conventional VACNT array absorbers grown from nanometer-order catalyst particles to heights of several hundred micrometers supported on silicon or other metal and ceramic materials, embodiments of the invention provide greater cohesion and can be more easily handled without falling apart or shedding nanotubes. Embodiments of the invention provided greater mechanical robustness, permitting the application of the resulting plasma-infused VACNT array to surfaces.

Also, the dramatic alteration of applique surface and porosity with the introduction a multi-spatial frequency surface contributes to the achievement of its exceptionally broadband low reflectance properties. The superior low reflection properties extending from the visible into the infrared wavelength region are shown in FIG. 3. The etched material makes a good absorber. Embodiments of the invention provide a wide size distribution of pores and wells, resulting in the broadband absorption characteristics, with low (less than approximately 1-2%) reflectance from visible wavelengths into infrared wavelengths, from approximately 300 nm to 2,400 nm, as seen in FIG. 3. If for example one is building a telescope, this results in superior stray light performance characteristics for one or more of the telescope barrel and the telescope baffle components.

For applying the nanocomposite absorbers to curved or complex shaped surfaces and/or applications involving large temperature swings or differentials, it is helpful if the polymer has a low (less than approximately 100 megapascals [MPa]) modulus and low (less than or equal to approximately 100° C.) glass transition temperature so that it remains flexible and pliable during application to component surfaces.

While the above representative embodiments have been described with certain components in exemplary configurations, it will be understood by one of ordinary skill in the art that other representative embodiments can be implemented using different configurations and/or different components. For example, it will be understood by one of ordinary skill in the art that the order of certain fabrication steps and certain components can be altered without substantially impairing the functioning of the invention.

The representative embodiments and disclosed subject matter, which have been described in detail herein, have been presented by way of example and illustration and not by way of limitation. It will be understood by those skilled in the art that various changes may be made in the form and details of the described embodiments resulting in equivalent embodiments that remain within the scope of the appended claims.

1. A method for making a vertically aligned carbon nanotube (VACNT) nanocomposite applique, comprising:
growing a VACNT array on a substrate that comprises an insulator;
treating the VACNT array with a polymer solution;
performing one or more of curing and drying the polymer;
and etching a surface of the polymer-VACNT nanocomposite to remove some of the polymer and to expose a portion of the VACNT.

2. The method of claim 1, wherein the step of growing comprises growing the VACNT array to a height of at least approximately 50 microns.

3. The method of claim 1, wherein the step of growing comprises growing the VACNT array to a height less than or equal to approximately 200 microns.

4. The method of claim 1, wherein the step of growing comprises growing the VACNT array to a height between approximately 50 microns and approximately 200 microns.

5. The method of claim 1, wherein the step of growing comprises growing the VACNT array with a density between approximately 3% and approximately 20%.

6. The method of claim 1, wherein the step of etching is performed using plasma.

7. The method of claim 1, wherein the step of etching is performed using one or more solvents.

8. The method of claim 7, wherein the step of etching is performed using one or more solvents that dissolves polyurethane.

9. The method of claim 1, further comprising infusing the VACNT array with a resin.

10. The method of claim 9, wherein the resin comprises a low viscosity polymer resin having a viscosity of less than approximately 100 pascal-seconds (PaS).

11. The method of claim 10, wherein the resin comprises one or more of resin in pure form and resin mixed with one or more solvents.

12. The method of claim 10, wherein the polymer resin comprises one or more of a polyurethane, a silicone, an epoxy, a polyether ether ketone (PEEK), and another polymer resin.

13. The method of claim 10, wherein the polymer resin comprises a thermoplastic polymer resin.

14. The method of claim 10, wherein the polymer resin comprises a thermosetting polymer resin.

15. A vertically aligned carbon nanotube (VACNT) nanocomposite applique, comprising:
a VACNT array; and
a polymer solution with which the VACNT array is treated,
wherein a surface of a polymer-VACNT nanocomposite is etched so as to do one or more of removing some of the polymer and exposing a portion of the VACNT.

16. The applique of claim 14, wherein the nanocomposite is etched using plasma.

17. The applique of claim 15, wherein the surface is etched using a solvent.

18. The applique of claim 16, wherein the surface is etched using a solvent that dissolves polyurethane.

19. The applique of claim 15, wherein VACNT array comprises a resin.

20. A method for making a vertically aligned carbon nanotube (VACNT) nanocomposite applique, comprising:
growing a VACNT array on a substrate that comprises an insulator to a height between approximately 50 microns and approximately 200 microns with a density between approximately 3% and approximately 20%;
treating the VACNT array with a polymer solution;
performing one or more of curing and drying the polymer;
and etching a surface of the polymer-VACNT nanocomposite with plasma to remove some of the polymer and to expose a portion of the VACNT.
